(19) United States
(12) Patent Application Publication
(10) Pub. No.: US 2007/0252180 A1
(43) Pub. Date: Nov. 1, 2007

(54) Semiconductor element, semiconductor device, and method for manufacturing the same

(76) Inventor: Mizuki Ono, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/785,945

(22) Filed: Apr. 23, 2007

(30) Foreign Application Priority Data
Apr. 25, 2006 (JP) 2006-120841

(51) Int. Cl. H01L 29/76

(52) U.S. Cl. 257/288

(57) ABSTRACT

A semiconductor element includes: a semiconductor region formed in a semiconductor substrate and containing an impurity of a predetermined conductivity type; source and drain regions formed to face each other in the semiconductor region, and containing a metal or a compound of a metal and a semiconductor forming the semiconductor region; a channel region located in the semiconductor region between the source region and the drain region; an insulating film covering the channel region and a part of each of the source and drain regions; and a gate electrode formed on the insulating film. A first portion of an interface between the insulating film and the gate electrode that is located above an at least partial region of the channel region exists closer to the semiconductor region than a second portion of the interface between the insulating film and the gate electrode located above each junction between the channel region and the source and drain regions.

### CROSS-REFERENCE TO RELATED APPLICATION

This application is based upon and claims the benefit of priority from prior Japanese Patent Application No. 2006-120841 filed on Apr. 25, 2006 in Japan, the entire contents of which are incorporated herein by reference.

### BACKGROUND OF THE INVENTION

1. Field of the Invention

The present invention relates to a semiconductor element, a semiconductor device, and a method for manufacturing the semiconductor element and the semiconductor device.

2. Related Art

In a conventional semiconductor device, shallow source and drain regions are required so as to prevent a short channel effect. At the same time, the resistance of the source and drain regions is required to be lowered, so as to reduce the parasitic resistance. To satisfy the two conflicting requirements, a so-called Schottky field effect transistor that has the source and drain regions formed with a metal or a material such as a metal silicide (or simply a silicide) has been developed.

Also, a recess gate structure has also been suggested so as to prevent a short channel effect (see U.S. Pat. No. 6,956,263 and United States Patent Application Publication No. 2004/0212024, for example).

Meanwhile, to increase the controllability of the gate electrode over the potential of the channel region, the equivalent oxide thickness of the gate insulating film (the value obtained by dividing the product of the actual thickness of the gate insulating film and the dielectric constant of silicon oxide by the dielectric constant of the gate insulating film) is required to be reduced. At the same time, to reduce the leakage current penetrating the gate insulating film and flowing into the gate electrode, the thickness of the gate insulating film is required to be reduced. To satisfy those requirements, it has been suggested to form the gate insulating film with a material (a high dielectric constant material) having a higher dielectric constant than silicon oxide, which has been conventionally used for the gate insulating film. As described above, the use of a metal for the source and drain regions and the use of a high dielectric constant material for the gate insulating film have been considered (see Shiyang Zhu et al., “Low temperature MOSFET technology with Schottky barrier source/drain, high-k gate dielectric and metal gate electrode”, Solid-State Electronics vol. 48 (2004) pp. 1987-1992, for example).

The semiconductor element disclosed in U.S. Pat. No. 6,956,263 has a recess structure overlapping the source and drain regions. As described in detail in the description of embodiments of the present invention, this semiconductor element has the problem of a low current drivability, according to the fact discovered by the inventor.

Meanwhile, the semiconductor element disclosed in United States Patent Application Publication No. 2004/0212024 has a structure in which the side faces of the gate electrode are aligned with the ends of the source and drain regions. As described in detail in the description of embodiments of the present invention, this semiconductor element has the problem of the gate electrode having poor controllability over the potential of the channel region, according to the fact discovered by the inventor.

In a Schottky field effect transistor, the resistance of the Schottky barrier formed at each junction between the channel region and the source and drain regions greatly affect the current drivability, and therefore, achieving a sufficiently high current drivability is difficult. Particularly, in a semiconductor element having the gate insulating film formed with a high dielectric constant material, the potential of the channel region becomes close to the potential of the source region, due to the capacitive coupling between the source region and the channel region caused by the lines of electric force penetrating the gate insulating film. Because of this, the Schottky barrier formed at each junction between the channel region and the source and drain regions becomes thick. As a result, the resistance of the Schottky barrier becomes higher, and the current drivability becomes lower. This problem has been a great hindrance to high-speed device operations.

### SUMMARY OF THE INVENTION

The present invention has been made in view of these circumstances, and an object thereof is to provide a semiconductor element that has a gate electrode with higher controllability over the electric potential of the channel region, and has a high current drivability. The present invention is also to provide a semiconductor device with the same characteristics as above, and a method for manufacturing the semiconductor element and the semiconductor device.

A semiconductor element according to a first aspect of the present invention includes: a semiconductor region formed in a semiconductor substrate and containing an impurity of a predetermined conductivity type; source and drain regions formed to face each other in the semiconductor region, and containing a metal or a compound of a metal and a semiconductor forming the semiconductor region; a channel region located in the semiconductor region between the source region and the drain region; an insulating film covering the channel region and a part of each of the source and drain regions; and a gate electrode formed on the insulating film, wherein a first portion of an interface between the insulating film and the gate electrode that is located above an at least partial region of the channel region exists closer to the semiconductor region than a second portion of the interface between the insulating film and the gate electrode located above each junction between the channel region and the source and drain regions.

A semiconductor element according to a second aspect of the present invention includes: a semiconductor region formed on a semiconductor substrate, containing an impurity of a predetermined conductivity type, and having the shape of a rectangular parallelepiped; source and drain regions formed at a distance from each other in a longitudinal direction of the semiconductor region, and containing a metal or a compound of a metal and a semiconductor forming the semiconductor region; a channel region formed in the semiconductor region between the source region and the drain region; a pair of insulating films covering a pair of faces of the semiconductor region serving as the channel region, and covering a part of each of the source and drain regions, the faces being located opposite to each other; and a pair of gate electrodes formed on the opposite faces of the pair of insulating films from the channel region, the pair of gate electrodes being connected to each other, wherein a first portion of an interface between each insulating film and each corresponding gate electrode that is located above an at least partial region of the channel region exists closer to the semiconductor region than a second portion of the interface between each insulating film and each corresponding gate electrode located above each junction between the channel region and the source and drain regions.

A semiconductor element according to a third aspect of the present invention includes: a plurality of semiconductor regions formed on a semiconductor substrate, containing an impurity of a predetermined conductivity type, and each having the shape of a rectangular parallelepiped; source and drain regions provided for each of the semiconductor regions, formed at a distance from each other in a longitudinal direction of each of the semiconductor regions, and containing a metal or a compound of a metal and a semiconductor forming the semiconductor region; a channel region provided for each of the semiconductor regions, and formed at each semiconductor region between the source region and the drain region; a pair of insulating films provided for each of the semiconductor regions, covering a pair of faces of the semiconductor region serving as the channel region, the faces being located opposite to each other, and covering a part of each of the source and drain regions; and a pair of gate electrodes provided for each of the semiconductor regions, and formed on the opposite faces of the pair of insulating films from the channel region, all of the gate electrodes being connected to each other, wherein a first portion of an interface between each insulating film and each corresponding gate electrode that is located above an at least partial region of each channel region exists closer to the semiconductor region than a second portion of the interface between each insulating film and each corresponding gate electrode located above each junction between the channel region and the source and drain regions.

A semiconductor device according to a fourth aspect of the present invention includes: the semiconductor element described-above, with holes being majority carriers in the semiconductor region; and the semiconductor element described-above, with electrons being majority carriers in the semiconductor region, the metal or the compound of a metal and a semiconductor that forms the source and drain regions containing Ni (nickel) or Co (cobalt).

A method for manufacturing a semiconductor element according to a fifth aspect of the present invention includes: introducing an impurity of a first conductivity type into a semiconductor substrate; forming a first insulating film on the semiconductor substrate; selectively removing the first insulating film to leave a part of the first insulating film; forming a second insulating film on the semiconductor substrate to cover the first insulating film; exposing at least an upper portion of the first insulating film by removing at least a part of the second insulating film; forming an opening to expose the semiconductor substrate at the bottom by removing the part of the first insulating film, the opening having side faces forming side faces of the second insulating film; forming a third insulating film to cover the second insulating film and the bottom face and the side faces of the opening; removing at least a part of the third insulating film by performing anisotropic etching on the third insulating film, the third insulating film remaining on the side faces of the opening; forming a groove in the semiconductor substrate by removing a part of the semiconductor substrate, with the second insulating film and the remaining third insulating film serving as masks; exposing the side faces of the second insulating film by removing the third insulating film; forming a fourth insulating film to cover at least the side faces of the second insulating film and the bottom face of the opening; forming a gate electrode film on the fourth insulating film, the gate electrode film covering the opening; exposing at least an upper portion of the second insulating film by removing at least parts of the fourth insulating film and the gate electrode film; removing the second insulating film; and forming source and drain regions on the semiconductor substrate.

The groove can be formed using an alkaline solution.

### BRIEF DESCRIPTION OF THE DRAWINGS

FIG. 1 is a cross-sectional view of a semiconductor element in accordance with a first embodiment;

FIG. 2 is a graph showing the current drivability of the semiconductor element of the first embodiment and semiconductor elements of Comparative Examples 1 and 2;

FIG. 3 is a graph showing the electric potential distributions of the semiconductor elements of the first embodiment and Comparative Examples 1, 2;

FIG. 4 is a cross-sectional view showing a structure in which the gate electrode is formed only on the side of the channel region in the vicinity of the source and drain regions;

FIG. 5 shows the dependence of the current drivability of the semiconductor element of the first embodiment on the size A and the size B shown in FIG. 1;

FIG. 6 shows the dependence of the current drivability of the semiconductor element of the first embodiment on the size A shown in FIG. 1;

FIGS. 7 through 11 are cross-sectional views showing the procedures for manufacturing the semiconductor element of the first embodiment;

FIG. 12 is a cross-sectional view of a semiconductor element in accordance with a second embodiment;

FIGS. 13 through 19 are cross-sectional views showing the procedures for manufacturing the semiconductor element of the second embodiment;

FIG. 20 is a perspective view of a semiconductor element in accordance with a third embodiment;

FIG. 21 is a cross-sectional view of the semiconductor element in accordance with the third embodiment, taken along the section plane C of FIG. 20;

FIG. 22 is a cross-sectional view of the semiconductor element in accordance with the third embodiment, taken along the section plane D of FIG. 20;

FIG. 23 is a perspective view of a semiconductor element in accordance with a fourth embodiment; and

FIG. 24 is a cross-sectional view of the semiconductor element in accordance with the fourth embodiment, taken along the section plane E of FIG. 23.

### DETAILED DESCRIPTION OF THE INVENTION

The following is a detailed description of embodiments of the present invention, with reference to the accompanying drawings. It should be noted that the present invention is not limited to the following embodiments, and various changes and modifications may be made to them.

### First Embodiment

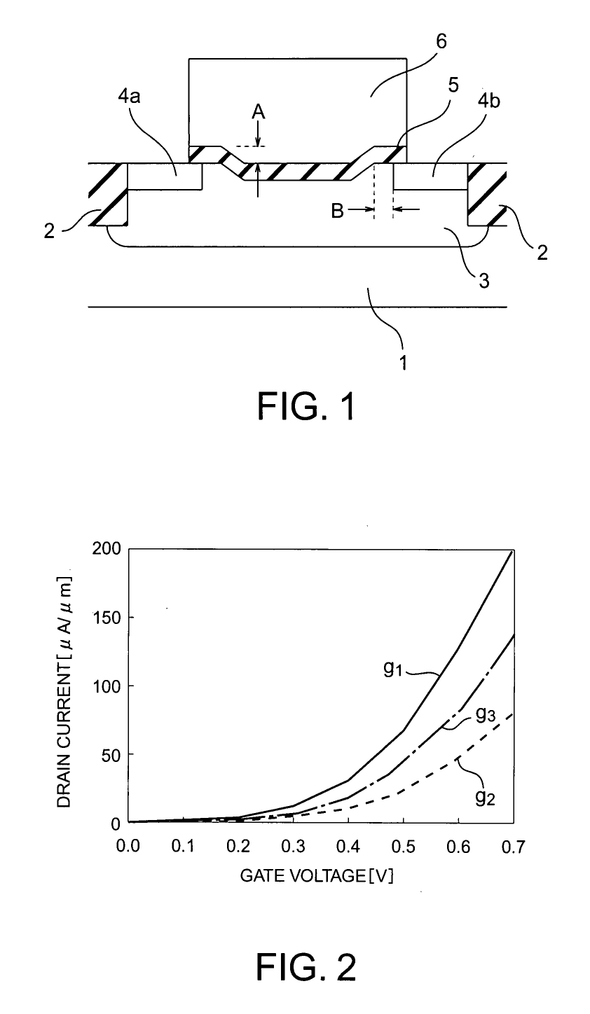

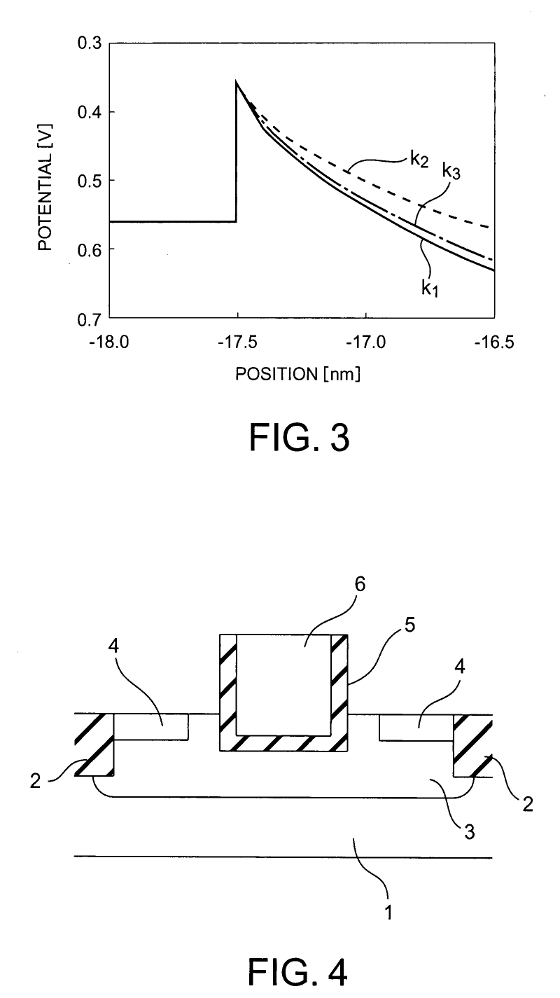

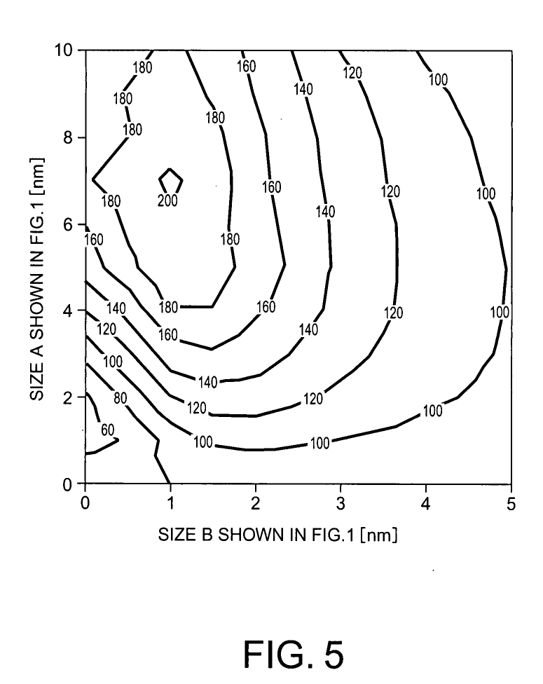

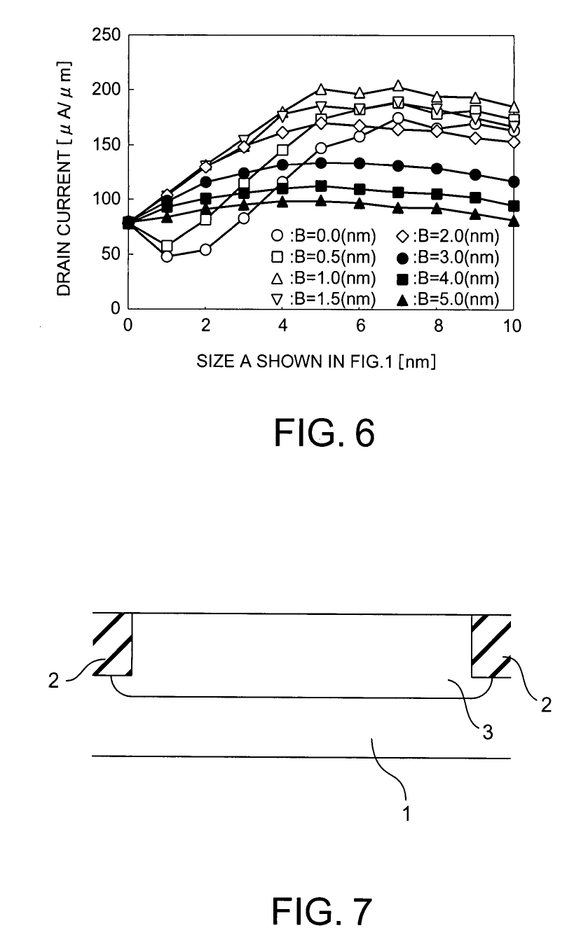

FIG. 1 is a cross-sectional view of a semiconductor element in accordance with a first embodiment of the present invention. The semiconductor element of this embodiment is a Schottky field effect transistor, and is formed on a semiconductor substrate 1. A semiconductor region 3 that contains an impurity of a certain conductivity type and serving as a channel region is formed inside a device isolating region 2 of the semiconductor substrate 1. A source region 4a and a drain region 4b are formed in the semiconductor region 3 in such a manner as to face each other. A gate electrode 6 is formed on a gate insulating film 5 formed on the portion of the semiconductor region 3 located between the source region 4a and the drain region 4b. The portion of the interface between the gate electrode 6 and the gate insulating film 5 that is located above the center portion of the semiconductor region 3 located between the source region 4a and the drain region 4b is closer to the semiconductor substrate 1 than the portion of the interface between the gate electrode 6 and the gate insulating film 5 that is located above the junctions between the semiconductor region 3 as the channel and the source and drain regions 4a, 4b. In this structure, the size A shown in FIG. 1 is not zero, and the gate electrode 6 is designed to surround the tops and sides of the end portions of the source region 4a and the drain region 4b that face each other. Also, the interface between the gate insulating film 5 and the semiconductor region 3 is flat between the junctions between the semiconductor region 3 as the channel and the source and drain regions 4a, 4b and the location at a predetermined distance (the size B shown in FIG. 1) from the junctions toward the center of the channel. However, the interface between the gate insulating film 5 and the semiconductor region 3 is inclined toward the semiconductor region 3 as it nears the center of the channel from the location at the predetermined distance, and is flat in the vicinity of the center of the channel. In FIG. 1, the interlayer insulating film, the wiring metal, the junction region between the gate electrode and the wiring metal, and the likes are not shown. It should be noted that the graphic scales of the respective components shown in FIG. 1 are not accurate.

The semiconductor element of this embodiment can achieve a much higher current drivability than a conventional element that has a flat interface between the gate electrode and the gate insulating film.

This fact is described in the following. The result of a calculation performed for determining the current drivability of a semiconductor element of this embodiment through a simulation is shown as graph g₁ in FIG. 2. The semiconductor element used in this simulation is an n-type Schottky field effect transistor. In this field effect transistor, the distance between the source region 4a and the drain region 4b is 35 nm, the equivalent oxide thickness of the gate insulating film 5 is 1 nm, the relative permittivity of the gate insulating film 5 is 20, the source region 4a and the drain region 4b are made of metal, the height of the Schottky barrier formed between the semiconductor region 3 as the channel and the source and drain regions 4a, 4b is 0.2 eV, and the junction depth of the source region 4a and the drain region 4b is 10 nm. The distance (indicated by A in FIG. 1) from the portion of the interface between the gate electrode 6 and the gate insulating film 5 that is located above the center portion of the semiconductor region 3 located between the source region 4a and the drain region 4b, to the portion of the interface between the gate electrode 6 and the gate insulating film 5 that is located above each junction between the semiconductor region 3 and the source and drain regions 4a, 4b, is 5 nm. Meanwhile, the distance from each junction between the semiconductor region 3 as the channel and the source and drain regions 4a, 4b to the point where the interface between the gate insulating film 5 and the semiconductor region 3 starts inclining toward the semiconductor substrate 1, or the distance (indicated by B in FIG. 1) from the source/drain regions 4a, 4b to the region in which the interface between the gate insulating film 5 and the gate electrode 6 is closer to the semiconductor substrate 1 than the portion of the interface between the gate insulating film 5 and the gate electrode 6 located above each junction between the semiconductor region 3 and the source and drain regions 4a, 4b, is 1 nm. Further, the potential of the source region 4a and the semiconductor substrate 1 is 0, and the drain voltage is 0.7 V. The drain current obtained where the drain voltage and the gate voltage are both 0.7 V is 198.7 μA/μm.

As Comparative Example 1, a simulation was performed for a semiconductor element having a conventional structure in which the interface between the gate electrode and the gate insulating film was flat above the source and drain regions and above the portion of the semiconductor region located between the source region and the drain region. This semiconductor element of Comparative Example 1 has the same structure as this embodiment, except that the interface between the gate electrode and the gate insulating film is flat. The gate voltage dependence of the drain current in Comparative Example 1 where the size A shown in FIG. 1 is “0” is shown by graph g₂ in FIG. 2. In the element of Comparative Example 1, the drain current obtained where the drain voltage and the gate voltage are both 0.7 V is 80.1 μA/μm.

Accordingly, the semiconductor element of this embodiment represented by the graph g₁ in FIG. 2 achieves approximately 247% of the current drivability of the element of Comparative Example 1. This is a fact discovered through this examination.

Also, as described as Related Art, the current drivability is lower in a Schottky field effect transistor having a gate insulating film made of a material with high dielectric constant. Therefore, as Comparative Example 2, a simulation was performed for a semiconductor element having the same structure as the semiconductor element of Comparative Example 1, except that the gate insulating film is replaced by a gate insulating film of 3.9 in relative permittivity (the value of the relative permittivity of silicon oxide). The result of the simulation performed for the semiconductor element of Comparative Example 2 is shown as graph g₃ in FIG. 2. The above described fact that “the current drivability is lower in a Schottky field effect transistor having a gate insulating film made of a material with high dielectric constant” is also proved by comparing the graph g₂ with the graph g₃ in FIG. 2.

In the semiconductor element of Comparative Example 2, the drain current obtained where the drain voltage and the gate voltage are both 0.7 V is 137.2 μA/μm. Accordingly, the semiconductor element of this embodiment represented by the graph g₁ in FIG. 2 achieves approximately 145% of the current drivability of the semiconductor element of Comparative Example 2. This is also a fact newly discovered through this examination.

As described above, the semiconductor element of this embodiment achieves a very high current drivability.

To determine the reason that the semiconductor element of this embodiment achieves a high current drivability, the potential distributions in the respective semiconductor elements of this embodiment, Comparative Example 1, and Comparative Example 2 were examined where the drain voltage and the gate voltage are both 0.7 V. FIG. 3 shows the electric potential distributions each observed on the substrate surface in the vicinity of the source region in each of the semiconductor elements of this embodiment, Comparative Example 1, and Comparative Example 2. In FIG. 3, the abscissa axis indicates the location along the substrate surface, with the center of the region (35 nm in length) between the source region 4a and the drain region 4b being zero. The region at −17.5 nm or less on the abscissa axis is the source region, and the region represented by values larger than −17.5 nm is the region between the source region 4a and the drain region 4b. The ordinate axis indicates the electric potential. Since the elements examined in this examination were of the n-type, the potential sensed by the carriers have the sign opposite to the sign of the electric potential. Therefore, the scale on the ordinate axis is larger where it is closer to the bottom. Also, the electric potentials shown in FIG. 3 contain the built-in potentials of the metal forming the source region and the semiconductor forming the region located between the source and drain regions. Graphs k₁, k₂, and k₃ represent this embodiment, Comparative Example 1, and Comparative Example 2, respectively.

As can be seen from FIG. 3, the electric potential of the region between the source region 4a and the drain region 4b is the highest in the semiconductor element of this embodiment. In other words, the semiconductor element of this embodiment has the thinnest Schottky barrier. The electric potential of the region between the source region 4a and the drain region 4b is the lowest in the semiconductor element of Comparative Example 1 (the element having a gate insulating film of 20 in relative permittivity). In other words, the semiconductor element of Comparative Example 1 has the thickest Schottky barrier. The electric potential of the region between the source region 4a and the drain region 4b in the semiconductor element of Comparative Example 2 is between the above two. This is also a fact discovered through this examination.

As described above, since the Schottky barrier formed at the junction between the source region and the channel region is thin in the semiconductor element of this embodiment, the resistance of the Schottky barrier of the semiconductor element of this embodiment is lower, and the semiconductor element of this embodiment achieves a high current drivability accordingly. This is yet another fact discovered through this examination.

Next, the reason that the Schottky barrier formed between the source region and the channel region is thin in the semiconductor element of this embodiment is examined. In the conventional element disclosed in the specification of United States Patent Application Publication No. 2004/0212024, for example, the gate electrode is formed only above the channel region in the vicinities of the source and drain regions. In an element having a structure in accordance with the present invention, on the other hand, the gate electrode is formed to surround the top and sides of the channel region in the vicinities of the source and drain regions and to have overlapping portions with the source and drain regions, as shown in FIG. 1. Accordingly, the gate electrode has higher controllability over the electric potential of the channel region in the vicinity of the source region. As a result, the electric potential of the channel region in the vicinity of the source region is closer to the electric potential of the gate electrode than to the electric potential of the source region. Thus, in the semiconductor element of this embodiment, the electric potential of the channel region in the vicinity of the source region is higher than that in a conventional semiconductor element, and the Schottky barrier is thinner. This fact was also newly found through this examination.

As described above, to achieve a high current drivability like the semiconductor element of this embodiment, it is essential to form the gate electrode so as to surround the top and sides of the channel region in the vicinities of the source and drain regions. If the portion of the interface between the gate electrode and the gate insulating film that is located closer to the semiconductor substrate than the portion of the interface between the gate electrode and the gate insulating film that is located above each junction between the channel region and the source and drain regions is formed only partially in the direction perpendicular to the principal direction of the current flowing in the element (the width direction of the element, or the direction perpendicular to the paper space), the region in which the interface between the gate electrode and the gate insulating film is not formed on the side of the semiconductor substrate when seen in the direction perpendicular to the principal direction of the current flowing in the element has a high resistance in the Schottky barrier. As a result, a high current drivability cannot be achieved. Therefore, the region in which the interface between the gate electrode and the gate insulating film is closer to the semiconductor substrate than the portion of the interface between the gate electrode and the gate insulating film located above each junction between the channel region and the source and drain regions should preferably be formed thoroughly in the direction perpendicular to the principal direction of the current flowing in the element. Also, as shown in FIG. 4, a structure in which the gate electrode 6 is formed only on the sides of the channel region in the vicinities of the source and drain regions 4a, 4b is not preferred either. To achieve a high current drivability, it is essential to form the gate electrode 6 on the top and the sides of the channel region in the vicinities of the source and drain regions 4a, 4b.

The next simulation was performed to determine preferred ranges of the depth (indicated by A in FIG. 1) of the region in which the interface between the gate electrode 6 and the gate insulating film 5 is formed near the channel region in the vicinity of the center of the channel region, and the distance (indicated by B in FIG. 1) from each junction between the semiconductor region 3 and the source and drain regions 4a, 4b to the point where the interface between the gate insulating film 5 and the semiconductor region 3 starts inclining toward the semiconductor region 3. FIG. 5 shows contour lines representing the drain current obtained through the simulation performed with varied depths and distances where the drain voltage and the gate voltage were both 0.7 V. In FIG. 5, the ordinate axis indicates the size A, and the abscissa axis indicates the size B. First, the preferred range of the depth (indicated by A in FIG. 1) of the region in which the interface between the gate electrode and the gate insulating film located above the center portion of the channel region is formed near the channel region is described. As can be seen from FIG. 5, to achieve a higher current drivability than the current drivability of the semiconductor element of Comparative Example 2 (137.2 μA/μm), the size A shown in FIG. 1 should preferably be 2 nm or larger. The size A is the longest possible distance from the portion of the interface between the gate electrode 6 and the gate insulating film 5 located in the region in which the interface between the gate electrode 6 and the gate insulating film 5 is close to the channel region, to the portion of the interface between the gate electrode 6 and the gate insulating film 5 that is located above each junction between the channel region and the source and drain regions 4a, 4b. The size B is the distance from the source and drain regions 4a, 4b to the region in which the interface between the gate electrode 6 and the gate insulating film 5 is close to the channel region.

As described above, to achieve a high current drivability in the semiconductor element of this embodiment, it is essential to have a thin Schottky barrier formed at the junction between the channel region and the source region. The Schottky barrier depends on the electric potential distribution in the vicinity of the junction between the source region and the channel region. The electric potential distribution varies in a similar manner depending on similar deformation of the semiconductor element. Therefore, the size A should preferably be twice the equivalent oxide thickness of the gate insulating film or larger. This is another fact discovered through this examination.

Next, the preferred range of the distance indicated by B in FIG. 1 from each junction between the semiconductor region 3 and the source and drain regions 4a, 4b to the point where the interface between the gate insulating film 5 and the semiconductor region 3 starts inclining toward semiconductor region 3 is described. As can be seen from FIG. 5, to achieve a higher current drivability than the current drivability of the semiconductor element of Comparative Example 2 (137.2 μA/μm), the size B shown in FIG. 1 should preferably be 3 nm or less. This implies that the size B should preferably be three times as large as the equivalent oxide thickness of the gate insulating film or less than that. This is another fact discovered through this examination.

FIG. 6 shows the dependence of the drain current on the size A shown in FIG. 1, where the drain voltage and the gate voltage are both 0.7 V. In FIG. 6, the size B shown in FIG. 1 is used as the parameter, and is varied from 0.0 nm to 0.5 nm to 1.0 nm to 1.5 nm to 2.0 nm to 3.0 nm to 4.0 nm to 5.0 nm. The semiconductor element having the value “0 nm” on the abscissa axis is a semiconductor element having a flat interface between the gate electrode and the gate insulating film, which is the semiconductor element of Comparative Example 1. As can be seen from FIG. 6, the semiconductor element in which the size B shown in FIG. 1 is 0.0 nm and the semiconductor element in which the size B shown in FIG. 1 is 0.5 nm might have a lower current drivability than the current drivability of the semiconductor element of Comparative Example 1, depending on the size A shown in FIG. 1. The other semiconductor elements have higher current drivability than the current drivability of the semiconductor element of Comparative Example 1. Accordingly, the size B shown in FIG. 1 should preferably be 1 nm or larger. This implies that the size B should preferably be equal to or larger than the equivalent oxide thickness of the gate insulating film. This is another fact discovered through this examination. Although the semiconductor element disclosed in U.S. Pat. No. 6,956,263 described above as the related art has a recess gate structure, it cannot achieve a high current drivability like the semiconductor element of this embodiment, as the size B is “0” in the conventional semiconductor element.

As described above, this embodiment can provide a semiconductor element in which the source and drain regions have a small junction depth and low resistance, the controllability of the gate electrode over the potential of the channel region is increased while the gate current is restrained, and the current drivability is high.

(Manufacturing Method)

Next, the method for manufacturing the semiconductor element in accordance with this embodiment is described.

As shown in FIG. 7, device isolation regions 2 are first formed in the semiconductor substrate 1 having the {100} plane by a trench device isolation method, for example. B (boron) ions are implanted into the p-well formation region, with an acceleration voltage of 100 keV and a dose amount of 2.0×10¹² cm⁻². Heat treatment at 1050° C. is then carried out for 30 seconds, so as to form the semiconductor region 3 containing a p-type impurity. The {100} plane is the (100) plane or a plane equivalent to the (100) plane in terms of crystallography. More specifically, a plane equivalent to the (100) plane in terms of crystallography is the (010) plane, the (001) plane, the (−100) plane, the (0-10) plane, or the (00-1) plane.

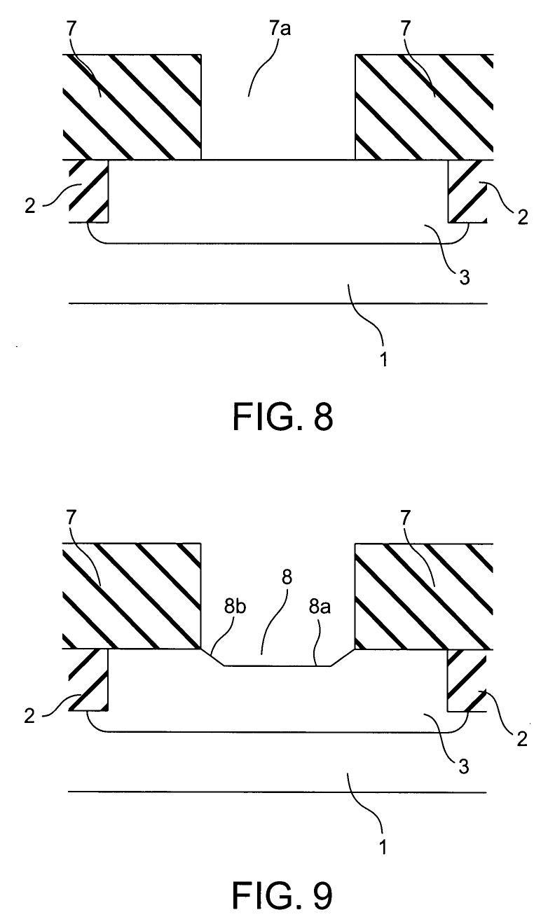

As shown in FIG. 8, a silicon nitride film 7 of 100 nm in thickness, for example, is formed by a chemical vapor deposition method (hereinafter referred to as the CVD method), and anisotropic etching such as reactive ion etching (hereinafter referred to as RIE) is performed on the silicon nitride film 7, so as to form an opening 7a to expose the semiconductor region 3 at the bottom surface.

Etching is further performed on the exposed semiconductor region 3 by immersing the structure in an alkaline solution such as a KOH (potassium hydroxide) solution, so as to form a groove 8 in the semiconductor region 3, as shown in FIG. 9. Here, the etching rate in the {111} plane is lower than the etching rate in the {100} plane that is the same as the semiconductor substrate 1. Therefore, the groove 8 is formed with a bottom face 8a having the {100} plane with a high etching rate, and side faces 8b having the {111} plane with a low etching rate. The {111} plane is the (111) plane or a plane equivalent to the (111) plane in terms of crystallography. More specifically, a plane equivalent to the (111) plane in terms of crystallography is the (−111) plane, the (1-11) plane, the (11-1) plane, the (−1-1-1) plane, the (−1-11) plane, the (−11-1) plane, or the (1-1-1) plane.

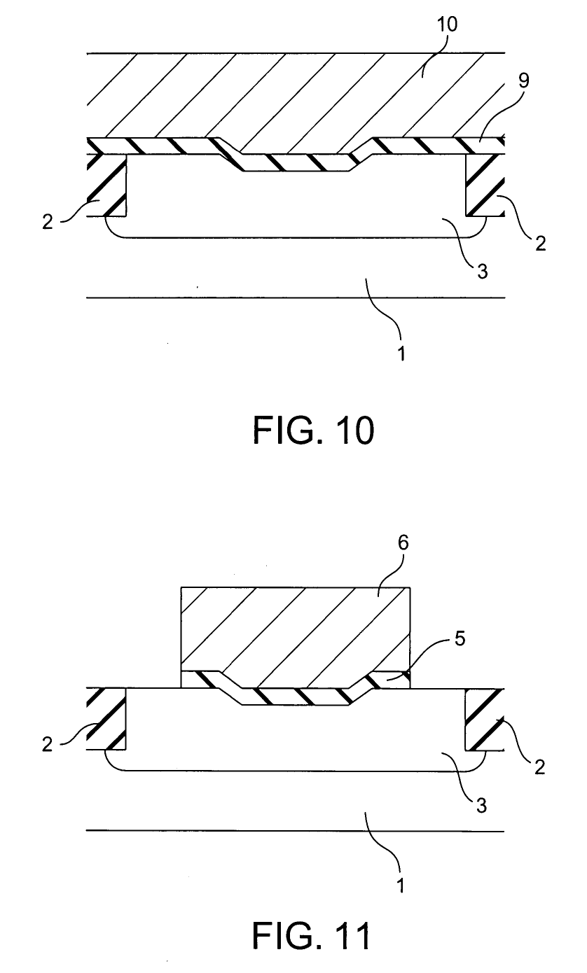

Thermal phosphoric acid treatment or the like is next carried out, so as to remove the silicon nitride film 7, as shown in FIG. 10. A HfO₂ (hafnium dioxide) film 9 of 5 nm in thickness, for example, is then formed by the CVD method or the like. A W (tungsten) film 10 of 100 nm in thickness, for example, is further formed by the CVD method or the like. The surface is then flattened by a chemical mechanical polishing method (hereinafter referred to as the CMP method) or the like.

Anisotropic etching such as RIE is then performed to process the W film 10 and the HfO₂ film 9, so that the gate electrode 6 and the gate insulating film 5 are formed, as shown in FIG. 11.

Next, Er (erbium) or the like is deposited on the surface of the semiconductor substrate 1, and heat treatment is carried out so as to form the source region 4a and the drain region 4b made of erbium silicide on the surface of the semiconductor substrate 1, as shown in FIG. 1. Thereafter, the interlayer insulating film forming process and the wire forming process are carried out by utilizing known techniques, so as to complete the semiconductor element of this embodiment.

In this embodiment, an n-type Schottky field effect transistor is taken as an example. However, with the conductivity type of the impurity being changed to the other one, a p-type Schottky field effect transistor can be formed in the same manner as above and can achieve the same effects as those of this embodiment. Also, with the impurity ions being implanted only into a specific region in the substrate by a photo-etching technique or the like, a complementary Schottky field effect transistor can be formed in the same manner as above and can achieve the same effects as those of this embodiment. Further, not only Schottky field effect transistors but also field effect transistors having sources and drains made of semiconductors containing impurities can achieve the same effects as those of this embodiment. This embodiment may also be applied to semiconductor devices that include those transistors as components.

Only the procedures for forming a Schottky field effect transistor have been described as the manufacturing method in accordance with this embodiment. However, the method in accordance with this embodiment may be applied not only to the manufacturing of Schottky field effect transistors but also to the manufacturing of active devices such as field effect transistors having sources and drains made of semiconductors containing impurities, bipolar transistors, and single-electron transistors, passive devices such as resistors, diodes, inductors, and capacitors, and Schottky field effect transistors to be used as parts of semiconductor devices including devices formed with ferroelectric substances or devices formed with magnetic substances. The method in accordance with this embodiment may also be applied to the manufacturing of Schottky field effect transistors to be used as parts of OEICs (opto-electrical integrated circuits) or parts of MEMSs (micro electro mechanical systems).

Although B (boron) is used as the impurity to form the p-type semiconductor region in this embodiment, any other III-group impurity may be used as the impurity to form the p-type semiconductor region. Although not mentioned above, a V-type impurity may be used as the impurity to form an n-type semiconductor region. The introduction of a III-group or V-group impurity may be performed with the use of a compound containing the impurity. In a case where a compound semiconductor is used, an impurity of some other group may be employed.

Although impurity introduction is performed through ion implantation in this embodiment, some other method such as a solid-phase diffusion method or a vapor-phase diffusion method may be utilized. Alternatively, a semiconductor containing an impurity may be deposited or grown.

Although Er is used to form the silicide layer that forms the source and drain regions in this embodiment, some other metal may be used. Also, the source and drain regions may be made of a metal, instead of a silicide. The use of a metal is advantageous in that the resistance of the source and drain region is made even lower. However, with the use of a silicide to form the source and drain regions as in this embodiment, the source and drain regions can be easily formed in a self-aligning manner with respect to the gate electrode and the device isolation regions, and the manufacturing procedures become simpler. Since the Fermi level of the source and drain regions of an n-type element should preferably have a close value to the lower end of the conduction band of the semiconductor used as the substrate, the work function of the metal or the compound formed with the metal and the semiconductor forming the source and drain regions should preferably be equal to or smaller than the difference between the center of the forbidden gap of the semiconductor forming the channel region and the electron vacuum level. In view of this, where a silicon substrate is used, it is preferable to employ Er, or a rare-earth element, or a metal such as Ti (titanium), Zr (zirconium), Hf (hafnium), Ta (tantalum), Nb (niobium), or Al (aluminum). Meanwhile, since the Fermi level of the source and drain regions of a p-type element should preferably have a close value to the higher end of the valence band of the semiconductor used as the substrate, the work functions of the metal or the compound formed with the metal and the semiconductor forming the source and drain-regions should preferably be equal to or larger than the difference between the center of the forbidden gap of the semiconductor forming the channel region and the electron vacuum level. In view of this, where a silicon substrate is used, it is preferable to employ a metal such as Pt (platinum), Pd (palladium), Ir (iridium), Re (rhenium), Ru (ruthenium), or W (tangsten). However, in a case where a complementary semiconductor device that includes both n-type and p-type elements is to be produced, the production procedures can be simplified by forming both n-type element and the p-type element with a material having the Fermi level close to the center of the forbidden gap of the semiconductor used as the substrate. In view of this, where a complementary semiconductor device having a silicon substrate is produced, it is preferable to use a metal such as Ni (nickel) or Co (cobalt). The same kinds of metals are preferred, whether a silicide layer or a metal is used to form the source and drain regions.

Although not mentioned above, an impurity may be introduced into the source and drain formation regions. Especially, high-concentration introduction of an impurity of the opposite conductivity type to the conductivity type of the channel region into the source and drain formation regions is advantageous in that the Schottky barrier formed at each junction between the channel region and the source and drain regions can be made thinner, and the resistance can be made lower accordingly.

Although the element is formed on a regular substrate, which is a bulk substrate, in this embodiment, a SOI (Silicon On Insulator) element may be formed on a SOI substrate. In such a case where a SOI element is formed, the impurity concentration in the channel region may be set so as to form a fully depleted element, or may be set so as to form a partially depleted element. To form a fully depleted element, the impurity concentration in the channel region is restricted to a low value. Accordingly, the carrier mobility increases, and the current drivability advantageously increases further. Thus, the advantage that the parasitic bipolar effect is restrained is also achieved.

In this embodiment, the element is formed on a bulk substrate, which is a single-crystal semiconductor. However, the element may be formed on a polycrystalline semiconductor or an amorphous semiconductor. In either case, the advantage that an element can be formed on a glass substrate or the like is achieved. Also, where an element is formed on a single-crystal semiconductor as in this embodiment, the channel region is formed with the single-crystal semiconductor. Accordingly, the carrier scattering in the channel is restrained, and a high current drivability can be achieved.

Although not mentioned in this embodiment, the semiconductor forming the substrate may be a IV-group semiconductor such as silicon or germanium, or a compound semiconductor such as GaAs (gallium arsenic), InP (indium phosphorus), InAs (indium arsenic), or InSb (indium antimony). Alternatively, a compound semiconductor formed with three or more elements may be employed.

Although W is used for the gate electrode in this embodiment, the gate electrode may be formed with a semiconductor such as polycrystalline silicon, single-crystal silicon, or amorphous silicon, a refractory metal or a metal not necessarily having a high melting point, a compound containing a metal, or a stack structure formed with those materials. Where the gate electrode is formed with a metal or a compound containing a metal, the gate resistance is restrained. Accordingly, a high-speed device operation can be achieved. Where the gate electrode is formed with a metal, an oxidizing reaction does not easily occur. Accordingly, the advantage that the controllability on the interface between the gate insulating film and the gate electrode is high is achieved. Where the gate electrode is at least partially formed with a semiconductor such as polycrystalline silicon, the work function can be easily controlled. Accordingly, the advantage that the threshold voltage of the element can be easily controlled is achieved. Where the gate electrode is formed with a semiconductor containing an impurity, the semiconductor containing an impurity may be deposited, and the impurity may be introduced by an ion implanting technique, a solid-phase diffusion method, or a vapor-phase diffusion method. When the semiconductor containing the impurity is deposited, high-concentration impurity introduction can be performed. As a result, the resistance can be made lower. Where an ion implanting technique is utilized, the procedures for forming a complementary semiconductor device including both an n-type element and a p-type element are advantageously simplified.

In this embodiment, the electrode is exposed through the upper portion of the gate electrode. However, an insulating material such as silicon oxide, silicon nitride, or silicon oxynitride may be provided at the upper portion. For example, where the gate electrode is formed with a material containing a metal, it is essential to provide a protection material such as silicon oxide, silicon nitride, or silicon oxynitride at the upper portion of the gate electrode if the gate electrode needs to be protected during the manufacturing process.

In this embodiment, the gate electrode is formed by performing anisotropic etching after a gate electrode material is deposited. However, the gate electrode may be formed by an embedding technique such as the damascene process.

In this embodiment, the gate electrode has the same lengths at the upper portion and the lower portion when measured in the principal direction of the current flowing in the element, but this aspect is not essential to this embodiment. For example, a “T”-shaped structure may be employed for the gate electrode, with the length of the upper portion being larger than the length of the lower portion. In such a case, the advantage that the gate resistance is made lower can be achieved.

In this embodiment, the gate insulating film is formed with a HfO₂ film formed by the CVD method. However, the gate insulating film may be formed with an oxide with a different valence of Hf (hafnium), or an oxide of another metal such as Zr (zirconium), Ti (titanium), Sc (scandium), Y (yttrium), Ta (tantalum), Al (aluminum), La (lanthanum), Ce (cerium), Pr (praseodymium), or a lanthanoid series element, or a silicate containing silicon as well as various elements such as the above elements, or an insulating film containing nitrogen as well as those elements, or a high dielectric constant film, or an insulating film having a stack structure formed with those elements. Where a high dielectric constant material is employed as above, the film thickness in terms of geometry can be made larger so as to achieve a desired equivalent oxide thickness. Accordingly, the gate current can be restrained, while the high controllability of the gate electrode over the potential of the channel region is maintained. Thus, a high dielectric constant film provides greater effects than a silicon oxide film that has been conventionally used as the gate insulating film, especially in a case where a material with a very high dielectric constant, such as a metal oxide, is used as the high dielectric constant film.

Furthermore, the existence of nitrogen in the insulating film is preferable, because it is prevented that certain elements in the insulating film crystallize and precipitate. The existence of nitrogen in the insulating film is preferable, also because impurity diffusion in the substrate can be restrained where a semiconductor containing an impurity is used as the gate electrode.

The formation of the insulating film may be carried out by a method such as a deposition method, a sputtering technique, or an epitaxial growth method, instead of the CVD method. In a case where an oxide of some material is used as the insulating film, a film made of the material may be first formed, and the film may be then oxidized to form the insulating film.

The gate insulating film may have a stack structure formed with a material with a high dielectric constant and a material with a low dielectric constant. In such a case, the gate current is restrained while the high controllability of the gate electrode over the potential of the channel region is maintained. At the same time, the capacitive coupling between the source region and the channel region via the gate insulating film can be restrained, and a decrease in current drivability can be prevented accordingly. Since the film thickness of the gate insulating film is smaller in terms of geometry than the film thickness of a gate insulating film that is formed only with a material having a high dielectric constant, deterioration of the controllability of the gate electrode over the potential of the channel region can be prevented. The deterioration is caused by the electric force lines generated from the gate and leaked from the side faces of the gate insulating film to the outside. In such a case, the film of the stacked-layer gate insulating film that is closer to the semiconductor layer may be a silicon oxide film, a silicon nitride film, or a silicon oxynitride film. Restraining the capacitive coupling caused between the source region and the channel region by the lines of electric force penetrating the gate insulating film can lead to an increase in current drivability. Therefore, this film should preferably have a low dielectric constant. This implies that it is preferable to use a silicon oxide film. With the film being formed with a silicon oxide film, the carrier mobility increases, and the current drivability also further increases. Since the amounts of charges and levels existing in the insulating film and in the interface with the semiconductor layer are preferably small, the film in contact with the semiconductor layer is preferably a silicon oxide film.

In a case where the gate electrode is formed with a semiconductor containing an impurity, the impurity in the gate electrode needs to be prevented from diffusing into the channel region. To do so, it is preferable to use silicon nitride or silicon oxynitride, as the existence of nitrogen prevents impurity diffusion. Also, those films can be formed by a depositing technique. In a case where silicon is used for the semiconductor layer, the insulating film can be formed by exposing silicon to oxygen or nitrogen in a temperature rising state, or by exposing silicon to an oxygen or nitrogen gas in an excited state without a temperature rise. The formation by the exposure to an oxygen or nitrogen gas in an excited state without a temperature rise is preferred, because a change in concentration distribution due to impurity diffusion in the channel region can be prevented.

In a case where silicon oxynitride is used, a silicon oxide film may be first formed, and the silicon oxide film may be then exposed to a nitrogen gas in a temperature rising state or an excited state, so as to introduce nitrogen into the insulating film. In this case, the formation by the exposure to a nitrogen gas in an excited state without a temperature rise is preferred, because a change in concentration distribution due to impurity distribution in the channel region can be prevented.

In a case where silicon oxynitride is used, a silicon nitride film may be first formed, and the silicon nitride film may be then exposed to a gas containing oxygen in a temperature rising state or an excited state, so as to introduce oxygen into the insulating film. In this case, the formation by the exposure to an oxygen gas in an excited state without a temperature rise is preferred, because a change in concentration distribution due to impurity distribution in the channel region can be prevented. Alternatively, the gate insulating film is not limited to a two-layer structure, but may have a stack structure formed with three layers.

Also, the thickness of the insulating film forming the gate insulating film is not limited to the value defined in this embodiment. Further, the gate insulating film has a uniform thickness, but this is not essential.

In this embodiment, the source and drain regions are formed after the gate electrode and the gate insulating film are formed. However, the source and drain regions may be formed before the gate electrode and the gate insulating film are formed. Where the source and drain regions are formed before the gate insulating film and the gate electrode are formed, the gate insulating film and the gate electrode are not exposed to the heat during the heating process for forming a compound of a metal and a semiconductor. Accordingly, this process order is advantageous where the gate electrode and the gate insulating film are made of a material that is not compatible with a temperature rise. In a case where the source and drain regions are formed after the gate electrode and the gate insulating film are formed as in this embodiment, the metal or the compound of a metal and a semiconductor that forms the source and drain regions is not exposed to the heat during the heating process for forming the gate electrode and the gate insulating film. Accordingly, this process order is advantageous where the source and drain regions are made of a material that is not compatible with a temperature rise.

Although the sidewalls of the gate electrode are not mentioned in this embodiment, the gate electrode may have sidewalls. With the sidewalls being provided, electric short-circuiting between the gate electrode and the source and drain regions can be prevented when the source and drain regions are formed.

Where the source and drain regions are formed without sidewalls as in this embodiment, high controllability can be achieved over the length of each extension of the source and drain regions under the gate electrode or the length of each overlapping portion between the gate electrode and the source and drain regions. In case the length of the overlapping portion is too long, parasitic capacitance is increased and in case the length of the overlapping portion is too short, parasitic resistance is increased. Hence, high controllability is required over the length of each extension of the source and drain regions under the gate electrode or the length of each overlapping portion between the gate electrode and the source and drain regions. Also, the manufacturing procedures can be simplified.

In this embodiment, the groove in the channel region is formed by immersing the structure in an alkaline solution, because the semiconductor substrate 1 has the (100) plane. However, the groove in the channel region may be formed by a method such as the RIE method or a chemical dry etching method (hereinafter referred to as the CDE method). Those methods such as the RIE method and the CDE method are often utilized in the procedures for manufacturing conventional semiconductor devices. Accordingly, the procedures can be easily controlled, and those methods can be utilized for semiconductor substrates not having the (100) plane. Also, the process of immersing the structure in an alkaline solution, such as a KOH (potassium hydroxide) solution or a TMAH (tetra methyl ammonium hydroxide), is advantageous in that the inclination angle of the sidewalls is determined by the plane orientation of the semiconductor in terms of crystallography and can be easily controlled accordingly.

In this embodiment, device isolation is performed by the trench device isolation method. However, devices may be isolated from one another by some other method such as a local oxidization method or a mesa device isolation method.

Although a post-oxidization process after the formation of the gate electrode is not mentioned in this embodiment, post-oxidization may be performed if the material of the gate electrode and the gate insulating film is compatible with post-oxidization. The corners of the lower end of the gate electrode may be rounded by performing a chemical process or by exposing the lower end of the gate electrode to a reactive gas, instead of post-oxidization. Those processes are preferred where it is possible to carry them out, because the electric field at each corner of the lower end of the gate electrode is relaxed where any of those processes is carried out.

Although the interlayer insulating film is not mentioned in this embodiment, a low dielectric constant material or the like, other than silicon, may be used as the interlayer insulating film. With the dielectric constant of the interlayer insulating film being low, the parasitic capacitance of the device is reduced, and a high-speed device operation can be achieved accordingly.

Although contact holes are not mentioned in this embodiment, self-aligning contacts may be formed. With self-aligning contacts being used, the device area can be reduced, and higher device integration can be achieved. Therefore, the use of self-aligning contacts is preferred.

Although not mentioned in this embodiment, the formation of a metal layer for wiring may be carried out by a sputtering technique or a deposition technique. Alternatively, the metal layer may be formed by a method such as a metal selective growth method or the damascene method. The material of the wiring metal may be Al (aluminum) containing silicon, or a metal such as Cu (copper). Particularly, Cu is preferred, having low resistivity.

Although the structure of a single element has been described as this embodiment, it should be understood that this embodiment is not limited to a single element and the same effects as above can be achieved in various other ways.

### Second Embodiment

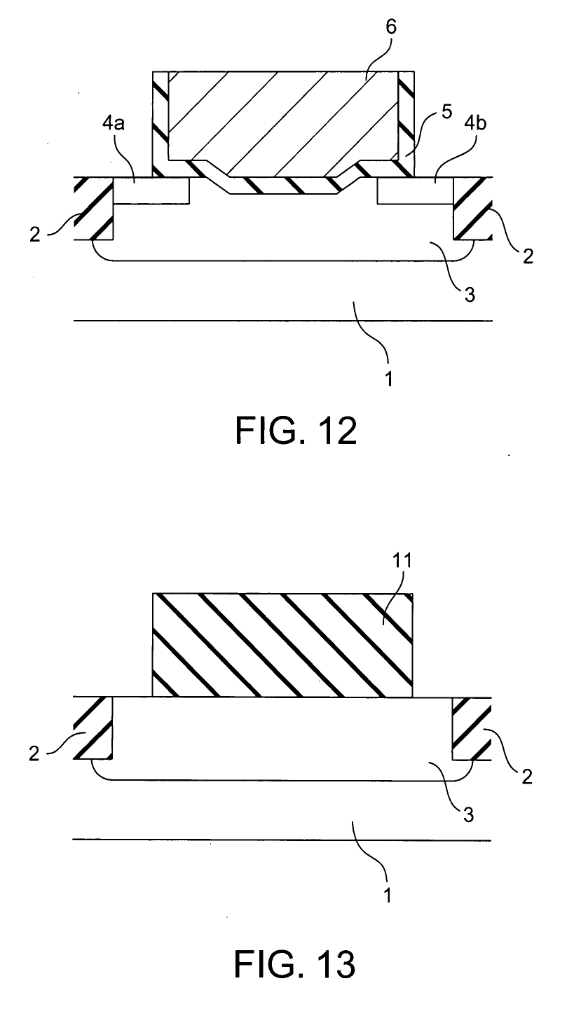

FIG. 12 is a cross-sectional view of a semiconductor element in accordance with a second embodiment of the present invention. The semiconductor element of this embodiment has the same structure as the semiconductor element of the first embodiment shown in FIG. 1, except that the gate insulating film 5 is also formed on the side faces of the gate electrode 6. In FIG. 12, the interlayer insulating film, the wiring metal, the junction regions between the gate electrode and the wiring metal, and the likes, are not shown. It should be noted that the scales of the respective components and parts shown in FIG. 12 are not accurate.

The following is a description of a method for manufacturing the semiconductor element of this embodiment.

After the procedure shown in FIG. 7, which shows a manufacturing procedure in accordance with the first embodiment, a silicon nitride film of 50 nm in thickness, for example, is formed by a method such as the CVD method. The silicon nitride film is then processed by an anisotropic etching method such as the RIE method, so as to form a dummy gate electrode 11, as shown in FIG. 13.

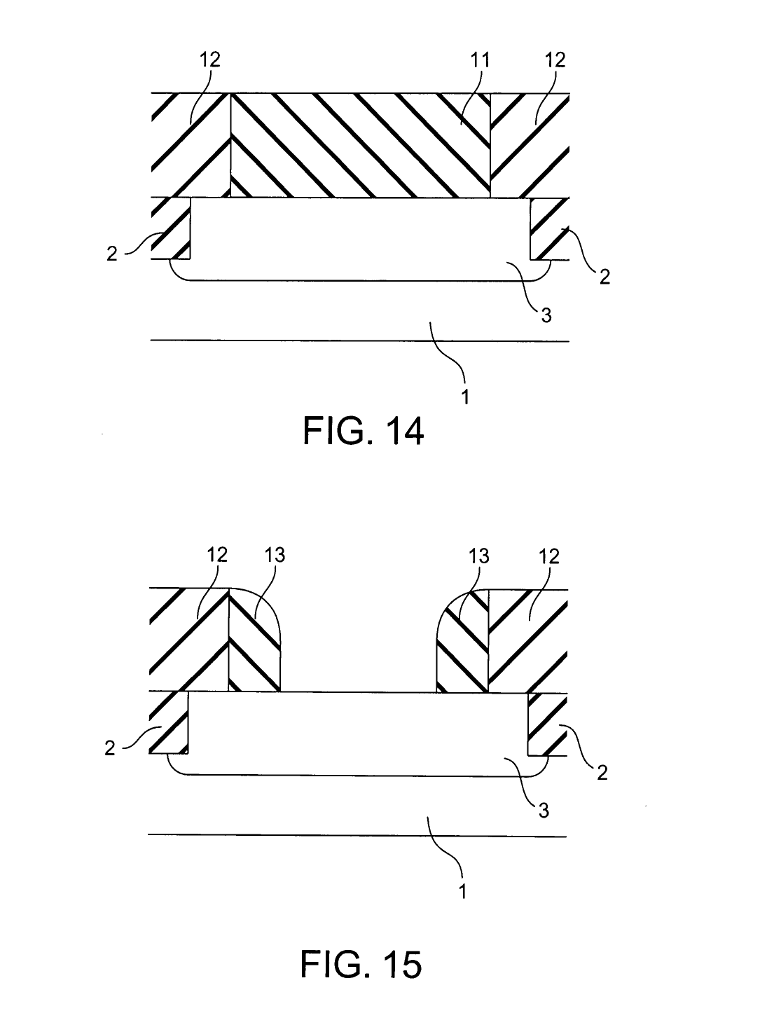

A silicon oxide film 12 of 100 nm in thickness, for example, is next formed on the semiconductor substrate 1 and the dummy gate electrode 11 by a method such as the CVD method. The surface of the silicon oxide film 12 is then flattened by a method such as the CMP method, so as to expose the upper portion of the dummy gate electrode 11, as shown in FIG. 14.

The dummy gate electrode 11 is next removed by a method such as thermal phosphorus acid treatment, so as to form an opening that exposes the semiconductor region 3 at the bottom, as shown in FIG. 15. A silicon nitride film of 10 nm in thickness, for example, is then formed by a method such as the CVD method, and the silicon nitride film is processed by an anisotropic etching method such as the RIE method, so as to form sidewalls 13 made of silicon nitride on the sides of the opening.

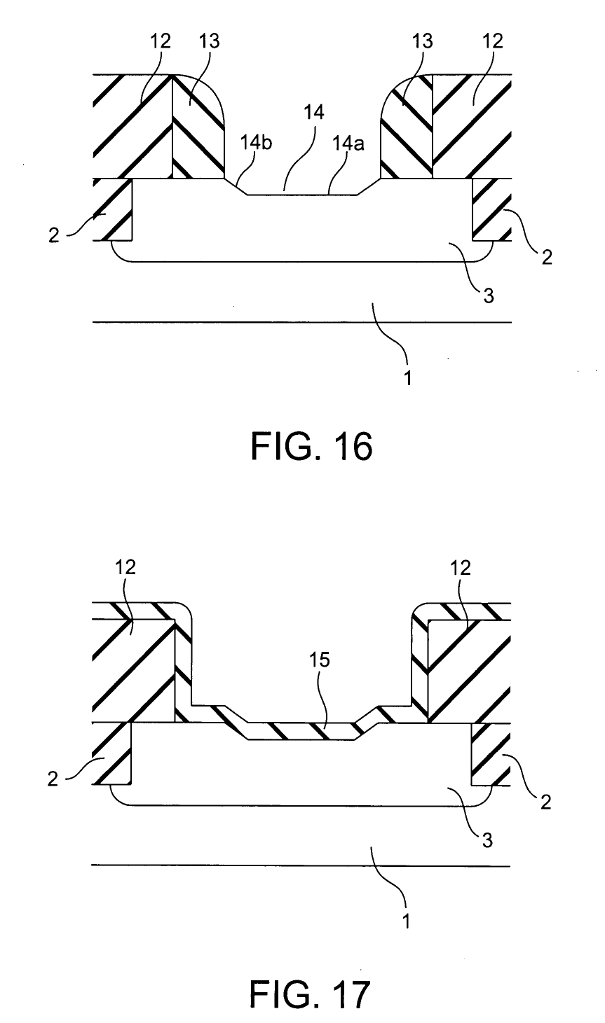

Next, as shown in FIG. 16, etching is performed to form a groove 14 in the exposed portion of the semiconductor region 3 by immersing the structure in an alkaline solution such as a KOH solution. This groove 14 is formed with a bottom face 14a having the (100) plane and side faces 14b each having the (111) plane, like the groove of the first embodiment shown in FIG. 9.

The sidewalls 13 are then removed by a method such as thermal phosphorus acid treatment, as shown in FIG. 17. An HfO₂ film 15 of 5 nm in thickness, for example, is then formed by a method such as the CVD method.

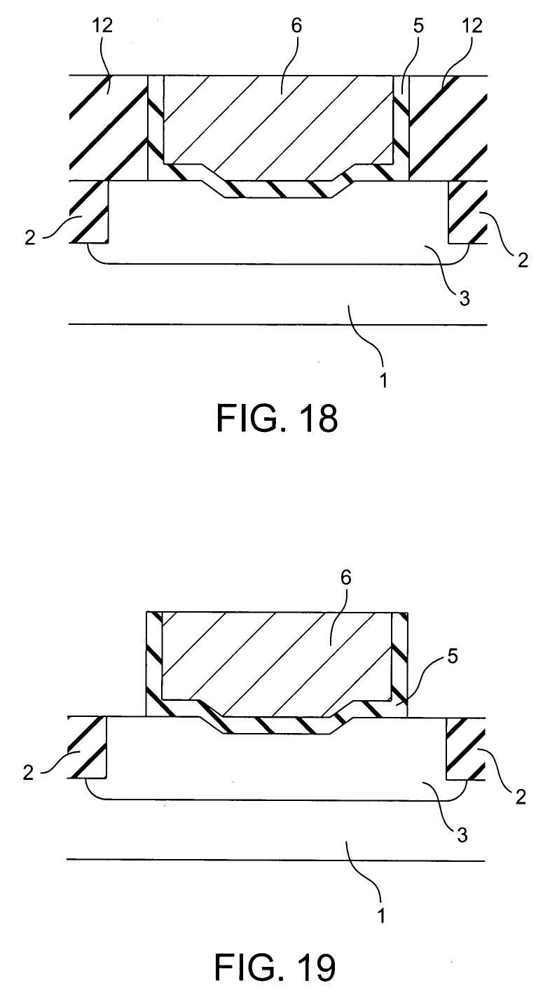

A W film of 100 nm in thickness, for example, is next formed by a method such as the CVD method, as shown in FIG. 18. The surfaces of the W film and the HfO₂ film 15 are then flattened by a method such as the CMP method, so as to expose the surface of the silicon oxide film 12. In this manner, the gate electrode 6 and the gate insulating film 5 are formed.

The silicon oxide film 12 is then removed by a method such as the RIE method, as shown in FIG. 19.

Thereafter, the procedures for forming the source and drain regions, the procedures for forming the interlayer insulating film, the procedures for forming the wirings, and the likes, are carried out as in the first embodiment. Thus, the semiconductor element of this embodiment shown in FIG. 12 is produced.

Where a semiconductor element is formed in the same manner as in this embodiment, the gate electrode and the source and drain regions are formed in a self-aligning manner with respect to the region in the center of the channel region in which the interface between the gate electrode and the gate insulating film is located close to the channel region.

Where a semiconductor element is formed by the manufacturing method in accordance with the first embodiment, on the other hand, the manufacturing procedures can be simplified. Also, where a semiconductor element is formed by the manufacturing method in accordance with the first embodiment, the material for the gate insulating film and the material for the sidewalls of the gate electrode, if the sidewalls are formed, can be selected independently of each other. Accordingly, a high dielectric constant material can be selected for the gate insulating film, so as to increase the controllability of the gate electrode over the potential of the channel region. A low dielectric constant material can be selected for the gate sidewalls, so as to restrain parasitic coupling between the side faces of the gate electrode and the source and drain regions.

Where a semiconductor element is formed in the same manner as in this embodiment, on the other hand, the gate insulating film and the gate sidewalls are simultaneously formed. Accordingly, the manufacturing procedures are simplified.

In a case where the source and drain regions are formed before the gate electrode and the gate insulating film are formed, the silicon oxide film formed to surround the gate electrode formation region can be used as the interlayer insulating film or as a part of the interlayer insulating film. In this manner, the manufacturing procedures are advantageously simplified.

As described above, this embodiment can provide a semiconductor element in which the source and drain regions have a small junction depth and low resistance, the controllability of the gate electrode over the potential of the channel region is increased while the gate current is restrained, and the current drivability is high. This embodiment can also provide the method for manufacturing such a semiconductor element.

Various changes and modifications as described for the first embodiment may also be made to this embodiment, and the same effects can be achieved.

### Third Embodiment

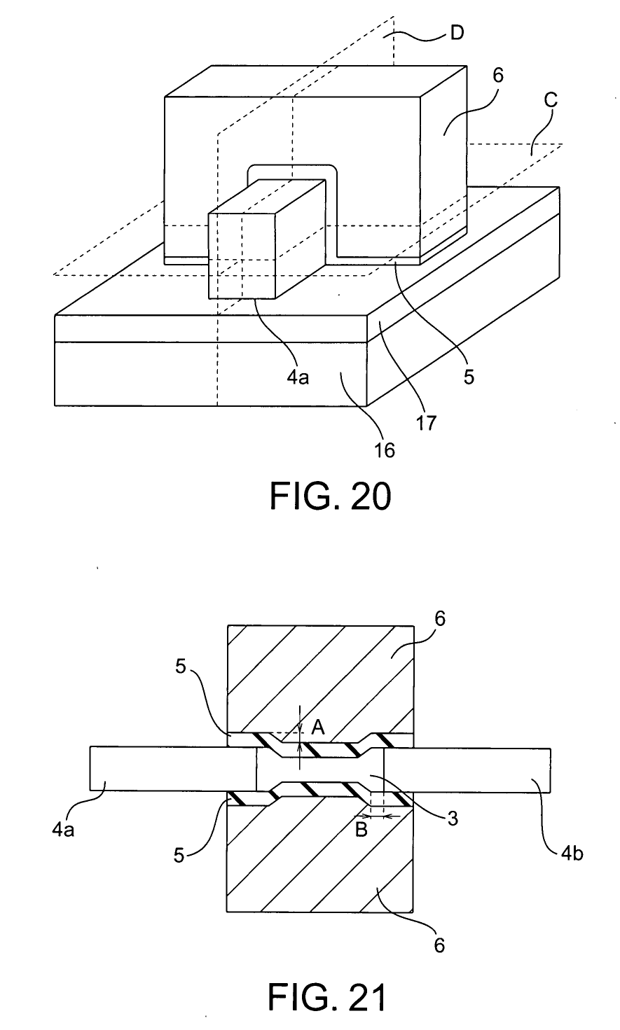

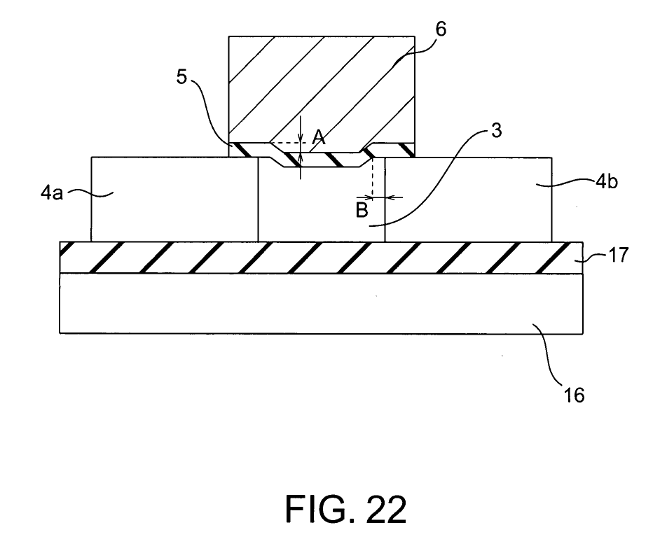

FIG. 20 is a perspective view of a semiconductor element in accordance with a third embodiment of the present invention. FIG. 21 is a cross-sectional view of the semiconductor element, taken along the section plane C of FIG. 20. FIG. 22 is a cross-sectional view of the semiconductor element, taken along the section plane D of FIG. 20. This semiconductor device is formed on a so-called SOI substrate that has a semiconductor layer formed on a supporting substrate 16, with an insulating film 17 being interposed between the semiconductor layer and the supporting substrate 16. The channel region 3 and the source and drain regions 4a and 4b are formed by processing the semiconductor layer. The drain region 4b exists behind the gate electrode 6, but is not shown in FIG. 20, being invisible because of the gate electrode 6. Also, the interlayer insulating film, the metal for wirings, the junction region between the gate electrode and the wiring metal, and the likes, are not shown in FIG. 20. It should be noted that the scales of the respective components and parts shown in FIG. 20 are not accurate.

Like the semiconductor element of the first embodiment shown in FIG. 1, the semiconductor element of this embodiment has a region in which the interface between the gate electrode 6 and the gate insulating film 5 is located close to the channel region. The longest possible distance A (see FIGS. 21 and 22) from the portion of the interface between the gate electrode 6 and the gate insulating film 5 in the region in which the interface between the gate electrode 6 and the gate insulating film 5 is located close to the channel region, to the portion of the interface between the gate electrode 6 and the gate insulating film 5 located above each junction between the channel region and the source and drain regions 4a, 4b, should be at least twice as much as the equivalent oxide thickness of the gate insulating film 5, as in the first embodiment. Also, the distance B (see FIGS. 21 and 22) from the region in which the interface between the gate electrode 6 and the gate insulating film 5 is located close to the channel region, to the source and drain regions 4a, 4b, is one to three times as much as the equivalent oxide thickness of the gate insulating film 5, as in the first embodiment.

In the semiconductor element of this embodiment, the channel region in the vicinity of the boundaries between the channel region 3 and the source and drain regions 4a, 4b is surrounded by the gate electrode 6 via the gate insulating film 5 from three directions, which are at the top and sides of the semiconductor layer and on the center of the channel region 3, in the vicinity of the ridge of the semiconductor layer forming the channel region 3 and the source and drain regions 4a, 4b. Accordingly, the same effects as those of the second embodiment can be achieved in a more prominent manner.

In this embodiment, the semiconductor layer to form the channel region 3 and the source and drain regions 4a, 4b is in contact with the gate insulating film 5 on the three surfaces, which are the top face and the two side faces of the plate-like semiconductor layer. However, this aspect is not essential to this embodiment. For example, a thick insulating film may be formed on the top face of the semiconductor layer, so that only the two side faces of the semiconductor layer are brought into contact with the gate insulating film 5.

In a case where the semiconductor layer to form the channel region 3 and the source and drain regions 4a, 4b is in contact with the gate insulating film only on two surfaces, the two surfaces are not necessarily the side faces of the semiconductor layer as described above. For example, a semiconductor layer having such a length that is much smaller when measured in the direction perpendicular to the surface of the semiconductor substrate than when measured in the direction parallel to the surface of the semiconductor substrate may be formed, so that the top and bottom faces of the semiconductor layer are brought into contact with the gate insulating film. Alternatively, the semiconductor layer may be processed into a stick-like form, and a gate electrode may be formed to surround the stick-like semiconductor layer. Further, in a semiconductor element having the gate insulating film in contact with two or more faces of the semiconductor layer to form the channel and the source and drain regions, the bottom of the gate electrode may not be flat in some plane, while may be flat in some other plane, as described in this embodiment as well as the first and second embodiment.

As described above, this embodiment can also provide a semiconductor element in which the source and drain regions have a small junction depth and low resistance, the controllability of the gate electrode over the potential of the channel region is increased while the gate current is restrained, and the current drivability is high.

Various changes and modifications as described for the foregoing embodiments may also be made to this embodiment, and the same effects can be achieved.

### Fourth Embodiment

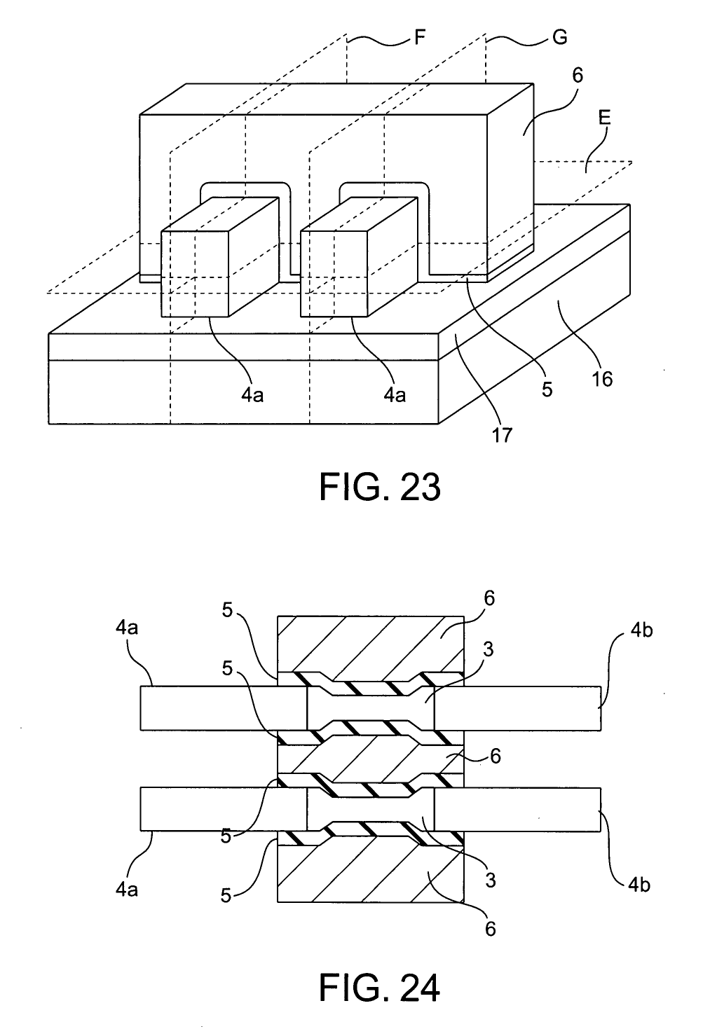

FIG. 23 is a perspective view of a semiconductor element in accordance with a fourth embodiment of the present invention. FIG. 24 is a cross-sectional view of the semiconductor element, taken along the section plane E of FIG. 23. Each section taken along the section planes F and G shown in FIG. 23 is the same as the section shown in FIG. 22. The semiconductor device of this embodiment is formed on a so-called SOI substrate that has a semiconductor layer formed on a supporting substrate 16, with an embedded insulating film 17 being interposed between the semiconductor layer and the supporting substrate 16. The channel regions 3 and the source and drain regions 4a, 4b are formed by processing the semiconductor layer. The source and drain regions 4a, 4b exist behind the gate electrode 6, but are not shown in FIG. 23, being invisible because of the gate electrode 6. Also, the interlayer insulating film, the metal for wirings, the junction region between the gate electrode and the wiring metal, and the likes, are not shown in FIG. 23. It should be noted that the scales of the respective components and parts shown in FIG. 23 are not accurate.

In the semiconductor element of this embodiment, the channel region in the vicinities of the boundaries between the channel regions 3 and the source and drain regions 4a and 4b is surrounded by the gate electrode 6 from three directions, which are at the top and sides of the semiconductor layer and on the center of each channel region 3, in the vicinity of the ridge of the semiconductor layer forming the channel regions 3 and the source and drain regions 4a, 4b. Accordingly, the same effects as those of the first and second embodiments can be achieved in a more prominent manner. Unlike the semiconductor element of the third embodiment, the semiconductor element of this embodiment has two source regions 4a, two drain regions 4b, and two channel regions 3. This is equivalent to a structure having two semiconductor elements of the third embodiment connected in parallel. As a result, a higher current drivability can be obtained. Further, in this embodiment, the gate electrode 6 is integrally formed to cover the two channel regions 3. Accordingly, the device area is made smaller than in a case where two semiconductor elements of the third embodiment are formed, and higher device integration can be achieved.

Although two source regions and two drain regions are formed in this embodiment, this aspect is not essential to this embodiment. For example, three or more source regions and three or more drain regions may be formed, so as to obtain an even higher current drivability. As two or more sets of source and drain regions exist, the semiconductor element of this embodiment can achieve a higher current drivability than the semiconductor element of the third embodiment. Also, as the gate electrode is integrally formed, higher device integration is achieved than in a case where semiconductor elements of the third embodiment are connected in parallel.

Various changes and modifications as described for the foregoing embodiments may also be made to this embodiment, and the same effects can be achieved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor element comprising:
a semiconductor region formed in a semiconductor substrate and containing an impurity of a predetermined conductivity type;
source and drain regions formed to face each other in the semiconductor region, and containing a metal or a compound of a metal and a semiconductor forming the semiconductor region;
a channel region located in the semiconductor region between the source region and the drain region;
an insulating film covering the channel region and a part of each of the source and drain regions; and
a gate electrode formed on the insulating film,
wherein a first portion of an interface between the insulating film and the gate electrode that is located above an at least partial region of the channel region exists closer to the channel region than a second portion of the interface between the insulating film and the gate electrode located above each junction between the channel region and the source and drain regions.

2. The semiconductor element according to claim 1, wherein:
majority carriers in the semiconductor region are holes; and
a work function of the metal or the compound of the metal and the semiconductor is equal to or smaller than the difference between the center of a forbidden gap of the semiconductor forming the semiconductor region and an electron vacuum level.

3. The semiconductor element according to claim 1, wherein:
majority carriers in the semiconductor region are electrons; and
a work function of the metal or the compound of the metal and the semiconductor is equal to or larger than the difference between the center of a forbidden gap of the semiconductor forming the semiconductor region and an electron vacuum level.

4. The semiconductor element according to claim 1, wherein a distance from the at least partial region of the channel region to the source and drain regions is one to three times as much as an equivalent oxide thickness of the insulating film.

5. The semiconductor element according to claim 1, wherein a longest distance from the first portion of the interface to the second portion of the interface is at least twice as much as an equivalent oxide thickness of the insulating film.

6. The semiconductor element according to claim 1, wherein the semiconductor region is formed with a single-crystal semiconductor.

7. The semiconductor element according to claim 6, wherein the at least partial region of the channel region has a first and second planes,
the first plane inclines toward a portion of an interface between the insulating film and the source and drain region that is located above each junction between the channel region and the source and drain regions, the first plane being the {111} plane, and
the second plane is parallel to the interface between the insulating film and the source and drain regions, the second plane being the {100} plane.

8. The semiconductor element according to claim 1, wherein the source and drain regions contain an impurity of the opposite conductivity type to the conductivity type of the portion of the channel region.

9. A semiconductor element comprising:
a semiconductor region formed on a semiconductor substrate, containing an impurity of a predetermined conductivity type, and having the shape of a rectangular parallelepiped;
source and drain regions formed at a distance from each other in a longitudinal direction of the semiconductor region, and containing a metal or a compound of a metal and a semiconductor forming the semiconductor region;
a channel region located in the semiconductor region between the source region and the drain region;
a pair of insulating films covering a pair of faces of the semiconductor region serving as the channel region, and covering a part of each of the source and drain regions, the faces being located opposite to each other; and
a pair of gate electrodes formed on the opposite faces of the pair of insulating films from the channel region, the pair of gate electrodes being connected to each other,
wherein a first portion of an interface between each insulating film and each corresponding gate electrode that is located above an at least partial region of the channel region exists closer to the channel region than a second portion of the interface between each insulating film and each corresponding gate electrode located above each junction between the channel region and the source and drain regions.

10. The semiconductor element according to claim 9, wherein:
majority carriers in the semiconductor region are holes; and
a work function of the metal or the compound of the metal and the semiconductor is equal to or smaller than the difference between the center of a forbidden gap of the semiconductor forming the semiconductor region and an electron vacuum level.

11. The semiconductor element according to claim 9, wherein:
majority carriers in the semiconductor region are electrons; and
a work function of the metal or the compound of the metal and the semiconductor is equal to or larger than the difference between the center of a forbidden gap of the semiconductor forming the semiconductor region and an electron vacuum level.

12. The semiconductor element according to claim 9, wherein a distance from the at least partial region of the channel region to the source and drain regions is one to three times as much as an equivalent oxide thickness of the insulating film.

13. The semiconductor element according to claim 9, wherein a longest distance from the first portion of the interface to the second portion of the interface is at least twice as much as an equivalent oxide thickness of the insulating film.

14. The semiconductor element according to claim 9, wherein the semiconductor region is formed with a single-crystal semiconductor.

15. The semiconductor element according to claim 14, wherein the at least partial region of the channel region has a first and second planes,
the first plane inclines toward a portion of an interface between the insulating film and the source and drain region that is located above each junction between the channel region and the source and drain regions, the first plane being the {111} plane, and
the second plane is parallel to the interface between the insulating film and the source and drain regions, the second plane being the {100} plane.

16. The semiconductor element according to claim 9, wherein the source and drain regions contain an impurity of the opposite conductivity type to the conductivity type of the portion of the channel region.

17. A semiconductor element comprising:
a plurality of semiconductor regions formed on a semiconductor substrate, containing an impurity of a predetermined conductivity type, and each having the shape of a rectangular parallelepiped;
source and drain regions provided for each of the semiconductor regions, formed at a distance from each other in a longitudinal direction of each of the semiconductor regions, and containing a metal or a compound of a metal and a semiconductor forming the semiconductor region;
a channel region provided for each of the semiconductor regions, and formed at each semiconductor region between the source region and the drain region;
a pair of insulating films provided for each of the semiconductor regions, covering a pair of faces of the semiconductor region serving as the channel region, the faces being located opposite to each other, and covering a part of each of the source and drain regions; and
a pair of gate electrodes provided for each of the semiconductor regions, and formed on the opposite faces of the pair of insulating films from the channel region, all of the gate electrodes being connected to each other,
wherein a first portion of an interface between each insulating film and each corresponding gate electrode that is located above an at least partial region of each channel region exists closer to the channel region than a second portion of the interface between each insulating film and each corresponding gate electrode located above each junction between the channel region and the source and drain regions.

18. A semiconductor device comprising:
the semiconductor element according to claim 1, with holes being majority carriers in the semiconductor region; and
the semiconductor element according to claim 1, with electrons being majority carriers in the semiconductor region,
the metal or the compound of a metal and a semiconductor that forms the source and drain regions containing Ni (nickel) or Co (cobalt).

19. A semiconductor device comprising:
the semiconductor element according to claim 9, with holes being majority carriers in the semiconductor region; and
the semiconductor element according to claim 9, with electrons being majority carriers in the semiconductor region,
the metal or the compound of a metal and a semiconductor that forms the source and drain regions containing Ni (nickel) or Co (cobalt).

20. A method for manufacturing a semiconductor element comprising:
introducing an impurity of a first conductivity type into a semiconductor substrate;
forming a first insulating film on the semiconductor substrate;
selectively removing the first insulating film to leave a part of the first insulating film;
forming a second insulating film on the semiconductor substrate to cover the part of the first insulating film;
exposing at least an upper portion of the first insulating film by removing at least a part of the second insulating film;
forming an opening to expose the semiconductor substrate at the bottom by removing the part of the first insulating film, the opening having side faces forming side faces of the second insulating film;
forming a third insulating film to cover the second insulating film and the bottom face and the side faces of the opening;
removing at least a part of the third insulating film by performing anisotropic etching on the third insulating film, the third insulating film remaining on the side faces of the opening;
forming a groove in the semiconductor substrate by removing a part of the semiconductor substrate, with the second insulating film and the remaining third insulating film serving as masks;
exposing the side faces of the second insulating film by removing the third insulating film;
forming a fourth insulating film to cover at least the side faces of the second insulating film and the bottom face of the opening;
forming a gate electrode film on the fourth insulating film, the gate electrode film covering the opening;
exposing at least an upper portion of the second insulating film by removing at least parts of the fourth insulating film and the gate electrode film;
removing the second insulating film; and
forming source and drain regions on the semiconductor substrate.
